(19) United States
(12) Patent Application Publication
(10) Pub. No.: US 2019/0386147 A1
(43) Pub. Date: Dec. 19, 2019

(54) LOWER TEMPERATURE POLYCRYSTAL SILICON THIN FILM TRANSISTOR AND MANUFACTURING METHOD THEREOF, DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Songshan LI, Wuhan, Hubei (CN)

(21) Appl. No.: 15/736,150

(22) PCT Filed: Sep. 6, 2017
(86) PCT No.: PCT/CN2017/100714

§ 371 Date: Dec. 13, 2017

(30) Foreign Application Priority Data
Jul. 27, 2017 (CN) 201710624553.8

(51) Int. Cl. H01L 29/786; H01L 29/417; H01L 29/167; H01L 29/66; H01L 21/266

(52) U.S. Cl. CPC H01L 29/78678; H01L 29/41733; H01L 21/266; H01L 29/4175; H01L 29/66765; H01L 29/167

(57) ABSTRACT

The present application provides a lower temperature polycrystal silicon thin film transistor, including: a substrate; a gate electrode; a gate insulating layer; a polycrystal silicon active layer including a polycrystal silicon bulk layer and a source electrode contact layer and a drain electrode contact layer located at both ends of the polycrystal silicon bulk layer, respectively; an etching stop layer including a first through hole and a second through hole, the first through hole exposing the source electrode contact layer, the second through hole exposing the drain electrode contact layer; a source and a drain electrode disposed on the etching stop layer, the source electrode filling the first through hole to contact with the source electrode contact layer, the drain electrode filling the second through hole to contact with the drain electrode contact layer; and a passivation layer disposed on the source, the drain electrode, and the etching stop layer.

### RELATED APPLICATIONS

The present application is a National Phase of International Application Number PCT/CN2017/100714, filed Sep. 6, 2017, and claims the priority of China Application No. 201710624553.8, filed Jul. 27, 2017.

### FIELD OF THE DISCLOSURE

The disclosure relates to a thin film transistor fabrication technology field, and more particularly to a lower temperature polycrystal silicon thin film transistor and a manufacturing method thereof, a display device.

### BACKGROUND

With the evolution of optoelectronics and semiconductor technologies, it has also led to the vigorous development of the flat panel display, and within many flat panel displays, liquid crystal display, LCD and organic light-emitting diode, OLED, by the high space utilization efficiency, low power consumption, no radiation and low electromagnetic interference and many other superior features, has become the mainstream of the market.

At present, amorphous silicon thin film transistor, a-Si TFT is widely used as a switching element of LCD and OLED display, but a-Si TFT LCD is still limited in satisfying the requirements of thin, light weight, high precision, high brightness, high reliability, Low power consumption. Lower temperature polycrystal silicon, LTPS TFT compared with a-Si TFT, in meeting the above requirements, has obvious advantages.

However, in the current lower temperature polycrystal silicon thin film transistor, because the source electrode and drain electrode can be in contact with the undoped polycrystal silicon layer, it will lead to the leakage current I_{off} of the lower temperature polycrystal silicon thin film transistor increased, thus affecting the characteristics of lower temperature polycrystal silicon thin film transistor, thereby affecting the display quality of LCD and OLED displays.

### SUMMARY

In order to solve the above-mentioned problems of the conventional technology, it is an object of the present invention to provide a lower temperature polycrystal silicon thin film transistor and a manufacturing method thereof, and a display device capable of reducing leakage current.

According to an aspect of the present invention, a lower temperature polycrystal silicon thin film transistor is provided, including; a substrate; a gate electrode disposed on the substrate; a gate insulating layer disposed on the gate electrode; a polycrystal silicon active layer disposed on the gate insulating layer, the polycrystal silicon active layer including a polycrystal silicon bulk layer and a source electrode contact layer and a drain electrode contact layer located at both ends of the polycrystal silicon bulk layer, respectively; an etching stop layer disposed on the gate insulating layer and the polycrystal silicon active layer, the etching stop layer including a first through hole and a second through hole, the first through hole exposing the source electrode contact layer, the second through hole exposing the drain electrode contact layer; a source electrode and a drain electrode disposed on the etching stop layer, the source electrode filling the first through hole to contact with the source electrode contact layer, the drain electrode filling the second through hole to contact with the drain electrode contact layer; and a passivation layer disposed on the source electrode, the drain electrode, and the etching stop layer.

Alternatively, the source electrode contact layer and the drain electrode contact layer is doped with boron ions.

Alternatively, the etching stop layer is formed of silicon oxide and/or silicon nitride.

According to another aspect of the present application, a display device is provided including the lower temperature polycrystal silicon thin film transistor.

According to another aspect of the present application, a method for manufacturing a lower temperature polycrystal silicon thin film transistor is provided, including the steps of; providing a substrate; forming a gate electrode on the substrate; forming a gate insulating layer on the substrate and the gate electrode; forming a polycrystal silicon layer on the gate insulating layer; forming an etching stop layer on the gate insulating layer and the polycrystal silicon layer; forming a first through hole and a second through hole in the etching stop layer, the first through hole exposing one end of the polycrystal silicon layer, the second through hole exposing the other end of the polycrystal silicon layer; forming one end of the exposed polycrystal silicon layer as the source electrode contact layer, and forming the other end of the polycrystal silicon layer as the drain electrode contact layer; forming a source electrode and a drain electrode on the etching stop layer, the source electrode filled with the first through hole to be in contact with the source electrode contact layer, the drain electrode filled with the second through hole to be in contact with the drain electrode contact layer; and forming a passivation layer on the source electrode, the drain electrode, and the etching stop layer.

Alternatively, the step of forming the polycrystal silicon layer on the gate insulating layer include; forming an amorphous silicon layer on the gate insulating layer; implanting ions to the amorphous silicon layer by an ion implantation technique; performing recrystallization to the amorphous silicon layer by a rapid thermal anneal technique, to form the polycrystal silicon layer and a polycrystalline silicon layer doped with ions on the polycrystal silicon layer; and removing the polycrystalline silicon layer doped with ions by dry etching.

Alternatively, the step of forming the first through hole and the second through hole in the etching stop layer includes: forming a photoresist layer on the etching stop layer; patterning the photoresist layer to form a first through hole and a second through hole to expose a portion of the etching stopper layer in the photoresist layer; and removing the exposed portion of the etching stop layer to form the first through hole and the second through hole in the etching stop layer.

Alternatively, the step of forming one end of the exposed polycrystal silicon layer as the source electrode contact layer, and forming the other end of the polycrystal silicon layer as the drain electrode contact layer including: implanting ions to one end and the other end of the polycrystal silicon layer by an ion implantation technique, respectively; performing rapid thermal anneal activation to the one end and the other end of the polycrystal silicon layer with the ion implanted; and removing the remaining photoresist layer.

Alternatively, the etching stop layer is formed of silicon oxide and/or silicon nitride.

Alternatively, the implanting ions by the ion implantation technique is boron ions.

Advantageous Effects of the Invention The present invention can prevent the source electrode and drain electrode from directly contacting the undoped polycrystal silicon layer, thereby reducing the leakage current of the lower temperature polycrystal silicon thin film transistor, and further improving the characteristics of the lower temperature polycrystal silicon thin film transistor.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the FIG.s:

FIG. 1 is a schematic structural view of a lower temperature polycrystal silicon thin film transistor according to an embodiment of the present invention;

FIGS. 2A to 2I are schematic manufacturing process diagrams of the lower temperature polycrystal silicon thin film transistor according to an embodiment of the present invention;

FIGS. 3A to 3C are schematic manufacturing process diagrams of a first through hole and a second through hole in an etching stop layer according to an embodiment of the present invention; and

FIGS. 4A to 4C are schematic manufacturing process diagrams of a source electrode contact layer and a drain electrode contact layer according to an embodiment of the present invention.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the description of the disclosure, terms such as “center”, “transverse”, “above”, “below”, “left”, “right”, “vertical”, “horizontal”, “top”, “bottom”, “inside”, “outside”, etc., for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure. Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the disclosure, unless otherwise indicated, the meaning of “plural” is two or more than two. In addition, the term “comprise” and any variations thereof are meant to cover a non-exclusive inclusion.

In the description of the disclosure, is should be noted that, unless otherwise clearly stated and limited, terms “mounted”, “connected with” and “connected to” should be understood broadly, for instance, can be a fixed connection, a detachable connection or an integral connection; can be a mechanical connection, can also be an electrical connection; can be a direct connection, can also be an indirect connection by an intermediary, can be an internal communication of two elements. A person skilled in the art can understand concrete meanings of the terms in the disclosure as per specific circumstances.

The terms used herein are only for illustrating concrete embodiments rather than limiting the exemplary embodiments. Unless otherwise indicated in the content, singular forms “a” and “an” also include plural. Moreover, the terms “comprise” and/or “include” define the existence of described features, integers, steps, operations, units and/or components, but do not exclude the existence or addition of one or more other features, integers, steps, operations, units, components and/or combinations thereof.

In the drawings, the thickness of the layers and regions is exaggerated in order to clarify the device. The same reference numerals refer to like elements throughout the specification and drawings.

It will be understood that when an element such as a layer, a film, a region, or a substrate is referred to as being “on” another element, the element may be directly on the other element, or an intermediate element may also be present. Optionally, there is no intermediate element when the element is referred to as being “directly” on the other element.

The disclosure will be further described in detail with reference to accompanying drawings and preferred embodiments as follows.

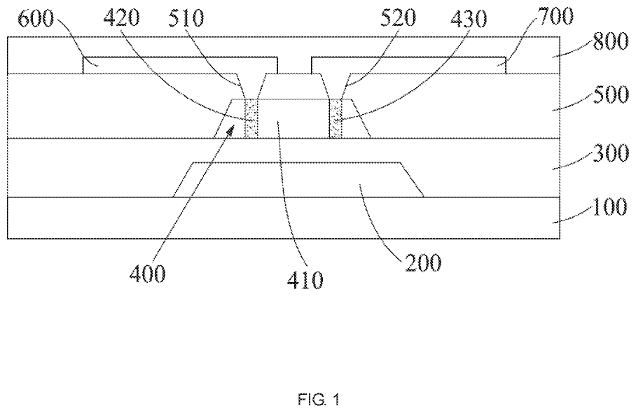

FIG. 1 is a schematic structural view of a lower temperature polycrystal silicon thin film transistor according to an embodiment of the present invention.

Referring to FIG. 1, the lower temperature polycrystal silicon thin film transistor according to the embodiment of the present invention includes a substrate 100, a gate electrode 200, a gate insulating layer 300, a polycrystal silicon active layer 400, an etching stop layer 500, a source electrode 600, a drain electrode 700, and a passivation layer 800.

Specifically, the substrate 100 may be, for example, a transparent glass substrate or a resin substrate, but the present invention is not limited thereto.

The gate electrode 200 is disposed on the substrate 100. The gate electrode 200 may be made of a molybdenum-aluminum-molybdenum, MoAlMo structure or a titanium-aluminum-titanium, TiAlTi structure, or may be a single-layer molybdenum structure or a single-layer aluminum structure, but the present invention is not limited thereto.

The gate insulating layer 300 is disposed on the gate electrode 200 and the substrate 100. Here, the gate insulating layer 300 may be, for example, a SiNiₓ/SiOₓ, structure formed on the gate electrode 200 and the substrate 100. However, the present invention is not limited thereto. For example, the gate insulating layer 300 may be a single layer of SiNₓ structure or SiOₓ structure.

The polycrystal silicon active layer 400 is disposed on the gate insulating layer 300. The polycrystal silicon active layer 400 includes a polycrystal silicon bulk layer 410 and a source electrode contact layer 420 and a drain electrode contact layer 430 located at both ends of the polycrystal silicon bulk layer 410, respectively. In the present embodiment, the source electrode contact layer 420 and the drain electrode contact layer 430 having boron ions implanted by the ion implantation technique, but the present invention is not limited thereto.

The etching stop layer 500 is disposed on the polycrystal silicon active layer 400 and the gate insulating layer 300, and the etching stop layer 500 has a first through hole 510 and a second through hole 520, the first through hole 510 exposes the source electrode contact layer 420, the second through hole 520 exposes the drain electrode contact layer 430. In the present embodiment, the etching stop layer 500 is formed of SiNₓ and/or SiOₓ, but the present invention is not limited thereto.

The source electrode 600 and the drain electrode 700 are disposed on the etching stop layer 500, the source electrode 600 fills the first through hole 510 to contact with the source electrode contact layer 420, the drain electrode 700 fills the second through hole 520 to contact with the drain electrode contact layer 430. The source electrode 600 and the drain electrode 700 may made be of a molybdenum-aluminum-molybdenum, MoAlMo structure or a titanium-aluminum-titanium, TiAlTi structure, or may be a single-layer molybdenum structure or a single-layer aluminum structure, but the present invention is not limited thereto.

The passivation layer 800 is disposed on the source electrode 600, the drain electrode 700, and the etching stop layer 500. In this embodiment, the passivation layer 800 is formed of silicon oxide, such as SiOₓ, but the present invention is not limited thereto.

The lower temperature polycrystal silicon thin film transistor according to the embodiment of the present invention can be applied to a display device, such as a liquid crystal display device and an organic light emitting diode, OLED display device. The lower temperature polycrystal silicon thin film transistor of the embodiment of the present invention can prevent the source electrode 600 and the drain electrode 700 from directly contacting the polycrystal silicon bulk layer 410, thereby reducing the leakage current of the lower temperature polycrystal silicon thin film transistor, thereby greatly improving the characteristics of the lower temperature polycrystal silicon thin film transistor.

The manufacturing method of the lower temperature polycrystal silicon thin film transistor according to the embodiment of the present invention will be described in detail below.

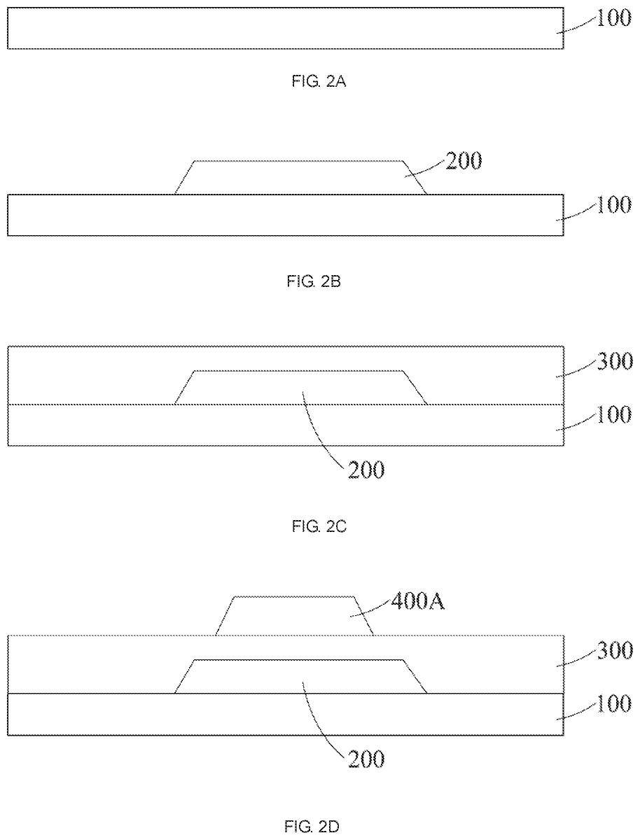

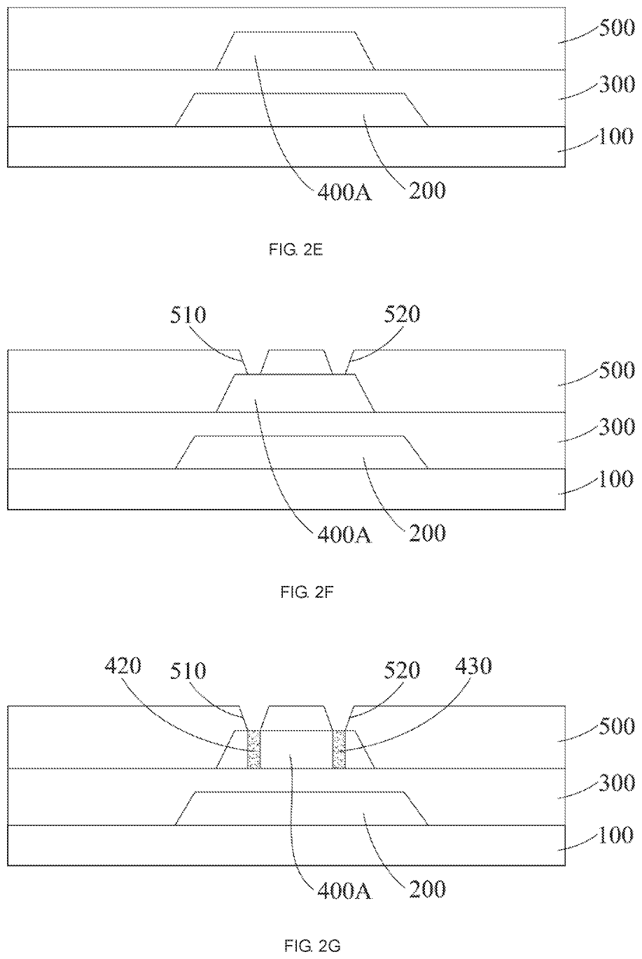

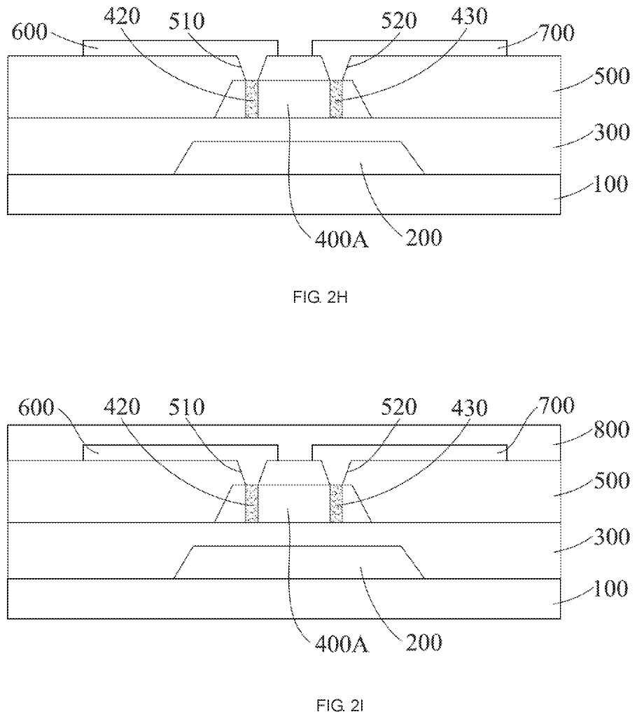

FIGS. 2A to 2I are schematic manufacturing process diagrams of the lower temperature polycrystal silicon thin film transistor according to the embodiment of the present invention.

A method for manufacturing a metal oxide thin film transistor according to an embodiment of the present invention includes:

Step 1: Referring to FIG. 2A, providing a substrate 100, the substrate 100 may be, for example, an insulated and transparent glass substrate or a resin substrate, but the present invention is not limited thereto.

Step 2: Referring to FIG. 2B, forming the gate electrode 200 on the substrate 100. The gate electrode 200 may be a molybdenum-aluminum molybdenum, MoAlMo structure or a titanium-aluminum-titanium, TiAlTi structure, or may be a single-layer molybdenum structure or a single-layer aluminum structure, but the present invention is not limited thereto.

Step 3: Referring to FIG. 2C, forming the gate insulating layer 300 on the substrate 100 and the gate electrode 200, Here, the gate insulating layer 300 may be, for example, a SiNiₓ/SiOₓ structure formed on a semiconductor body layer 210. However, the present invention is not limited thereto. For example, the gate insulating layer 300 may be a single layer of SiNₓ structure or SiOₓ structure.

Step 4: Referring to FIG. 2D, forming a polycrystal silicon layer 400A on the gate insulating layer 300.

Here, the method of forming the polycrystal silicon layer 400A specifically includes: first, forming an amorphous silicon layer on the gate insulating layer 300 by plasma enhanced chemical vapor deposition, PECVD; and then implanting ions, e.g., boron ions, etc. to the amorphous silicon layer by the ion implantation technique; followed, performing recrystallization to the amorphous silicon layer by the method of rapid thermal anneal, thereby forming the polycrystal silicon layer 400A and a polycrystalline silicon layer doped with ions on the polycrystal silicon layer 400A; And finally, the polycrystalline silicon layer doped with ions is removed by dry etching.

Step 5: Referring to FIG. 2E, forming the etching stop layer 500 on the gate insulating layer 300 and the polycrystal silicon layer 400A. Here, the etching stop layer 500 is formed of silicon oxide, such as SiOₓ and/or silicon nitride, such as SiNₓ, but the present invention is not limited thereto.

Step 6, Referring to FIG. 2F, forming the first through hole 510 and the second through hole 520 in the etching stop layer 500, the first through hole 510 exposing one end of the polycrystal silicon layer 400A, the second through hole 520 exposing the other end of the polycrystal silicon layer 400A.

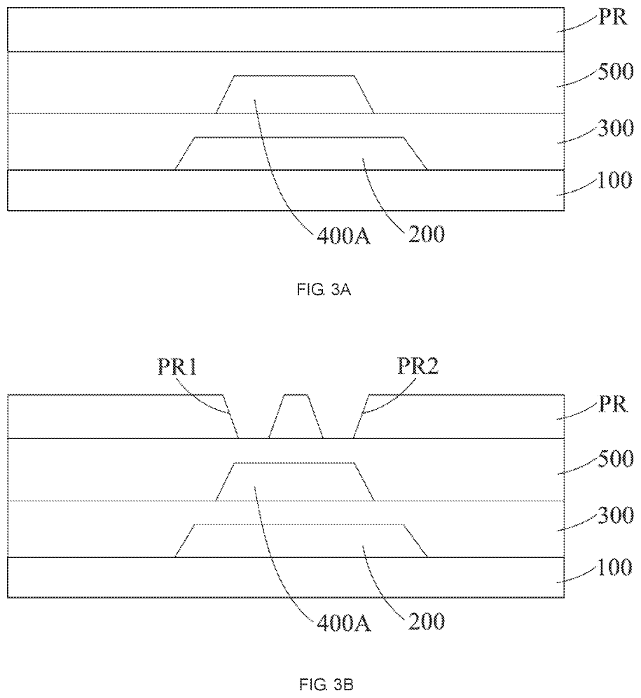

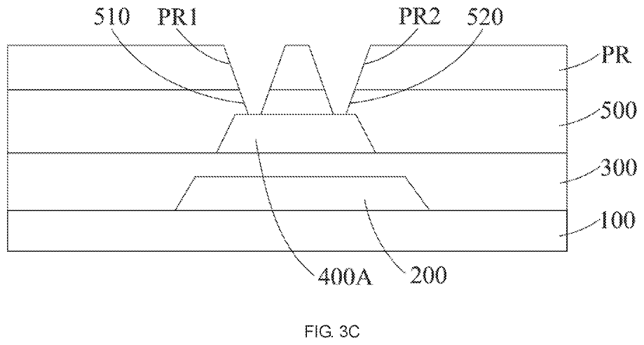

FIGS. 3A to 3C are schematic manufacturing process diagrams of the first through hole and the second through hole in the etching stop layer according to the embodiment of the present invention. The method of forming the first through hole 510 and the second through hole 520 in the etching stop layer according to the embodiment of the present invention includes: first, Referring to FIG. 3A, forming a photoresist layer PR on the etching stop layer 500; followed, referring to FIG. 3B, patterning the photoresist layer PR to form a first through hole PR1 and a second through hole PR2 for exposing a portion of the etching stopper layer 500 in the photoresist layer PR; finally, referring to FIG. 3C, removing the exposed portion of the etching stop layer 500 to form the first through hole 510 and the second through hole 520 in the etching stop layer 500.

Step 7: Referring to FIG. 2G, forming one end of the exposed polycrystal silicon layer 400A as the source electrode contact layer 420, and forming the other end of the polycrystal silicon layer 400A as the drain electrode contact layer 430. Wherein, the portion other than the source electrode contact layer 420 and the drain electrode contact layer 430 of the polycrystal silicon layer 400A is the polycrystal silicon bulk layer 410 shown in FIG. 1, so that the polycrystal silicon bulk layer 410, the source electrode contact layer 420, and the drain electrode contact layer 430 constitute the polycrystal silicon active layer 400 shown in FIG. 1.

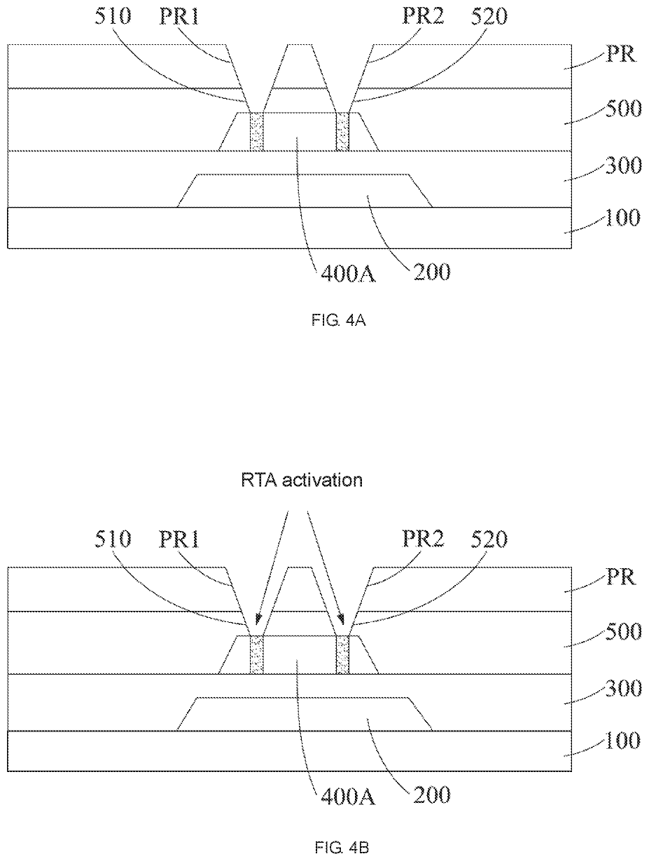

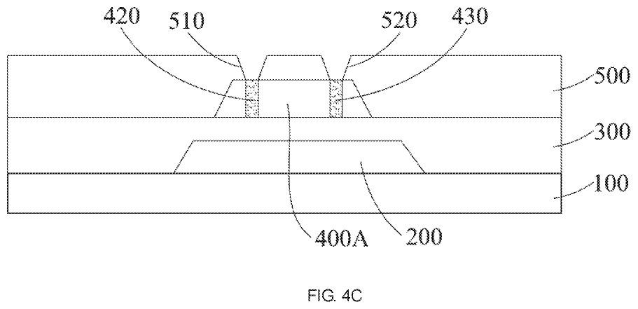

FIGS. 4A to 4C are schematic manufacturing process diagrams of the source electrode contact layer and the drain electrode contact layer according to an embodiment of the present invention. The method of forming the source electrode contact layer and the drain electrode contact layer according to the embodiment of the present invention includes: first, referring to FIG. 4A, implanting ions, e.g., boron ions to one end and the other end of the polycrystal silicon layer 400A by the ion implantation technique, respectively; followed, referring to FIG. 4B, performing rapid thermal anneal, RTA activation to the one end and the other end of the polycrystal silicon layer 400A with the ion implanted; finally, referring to FIG. 4C, etching to remove the remaining photoresist layer PR.

Step 8: Referring to FIG. 2H, forming the source electrode 600 and the drain electrode 700 on the etching stop layer 500, the source electrode 600 is filled with the first through hole 510 to be in contact with the source electrode contact layer 420, the drain electrode 700 is filled with the second through hole 520 to be in contact with the drain electrode contact layer 430. The source electrode 600 and the drain electrode 700 may be made of a molybdenum aluminum molybdenum, MoAlMo structure or a titanium aluminum titanium, TiAlTi structure, or may be a single-layer molybdenum structure or a single-layer aluminum structure, but the present invention is not limited thereto.

Step 9: referring to FIG. 9, forming the passivation layer 800 on the source electrode 600, the drain electrode 700, and the etching stop layer 500. Here, the passivation layer 800 is formed of silicon oxide, such as SiOₓ, but the present invention is not limited thereto.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A lower temperature polycrystal silicon thin film transistor, comprising;
a substrate;
a gate electrode disposed on the substrate;
a gate insulating layer disposed on the gate electrode;
a polycrystal silicon active layer disposed on the gate insulating layer,
the polycrystal silicon active layer comprising a polycrystal silicon bulk layer and a source electrode contact layer and a drain electrode contact layer located at both ends of the polycrystal silicon bulk layer, respectively;
an etching stop layer disposed on the gate insulating layer and the polycrystal silicon active layer, the etching stop layer comprising a first through hole and a second through hole, the first through hole exposing the source electrode contact layer, the second through hole exposing the drain electrode contact layer;
a source electrode and a drain electrode disposed on the etching stop layer, the source electrode filling the first through hole to contact with the source electrode contact layer, the drain electrode filling the second through hole to contact with the drain electrode contact layer; and
a passivation layer disposed on the source electrode, the drain electrode, and the etching stop layer.

2. The lower temperature polycrystal silicon thin film transistor according to claim 1, wherein the source electrode contact layer and the drain electrode contact layer are doped with boron ions.

3. The lower temperature polycrystal silicon thin film transistor according to claim 1, wherein the etching stop layer is formed of silicon oxide and/or silicon nitride.

4. A display device, comprising the lower temperature polycrystal silicon thin film transistor according to claim 1.

5. A method for manufacturing a lower temperature polycrystal silicon thin film transistor, comprising the steps of:
providing a substrate;
forming a gate electrode on the substrate;
forming a gate insulating layer on the substrate and the gate electrode;
forming a polycrystal silicon layer on the gate insulating layer;
forming an etching stop layer on the gate insulating layer and the polycrystal silicon layer;
forming a first through hole and a second through hole in the etching stop layer, the first through hole exposing one end of the polycrystal silicon layer, the second through hole exposing the other end of the polycrystal silicon layer;
forming one end of the exposed polycrystal silicon layer as the source electrode contact layer, and forming the other end of the polycrystal silicon layer as the drain electrode contact layer;
forming a source electrode and a drain electrode on the etching stop layer, the source electrode filled with the first through hole to be in contact with the source electrode contact layer, the drain electrode filled with the second through hole to be in contact with the drain electrode contact layer; and
forming a passivation layer on the source electrode, the drain electrode, and the etching stop layer.

6. The method for manufacturing the lower temperature polycrystal silicon thin film transistor according to claim 5, wherein the step of forming the polycrystal silicon layer on the gate insulating layer comprise:
forming an amorphous silicon layer on the gate insulating layer;
implanting ions to the amorphous silicon layer by an ion implantation technique;
performing recrystallization to the amorphous silicon layer by a rapid thermal anneal technique, to form the polycrystal silicon layer and a polycrystalline silicon layer doped with ions on the polycrystal silicon layer; and
removing the polycrystalline silicon layer doped with ions by dry etching.

7. The method for manufacturing the lower temperature polycrystal silicon thin film transistor according to claim 5, wherein the step of forming the first through hole and the second through hole in the etching stop layer comprises:
forming a photoresist layer on the etching stop layer;
patterning the photoresist layer to form a first through hole and a second through hole to expose a portion of the etching stopper layer in the photoresist layer; and
removing the exposed portion of the etching stop layer to form the first through hole and the second through hole in the etching stop layer.

8. The method for manufacturing the lower temperature polycrystal silicon thin film transistor according to claim 6, wherein the step of forming the first through hole and the second through hole in the etching stop layer comprises:
forming a photoresist layer on the etching stop layer;
patterning the photoresist layer to form a first through hole and a second through hole to expose a portion of the etching stopper layer in the photoresist layer; and
removing the exposed portion of the etching stop layer to form the first through hole and the second through hole in the etching stop layer.

9. The method for manufacturing the lower temperature polycrystal silicon thin film transistor according to claim 7, wherein the step of forming one end of the exposed polycrystal silicon layer as the source electrode contact layer, and forming the other end of the polycrystal silicon layer as the drain electrode contact layer comprising:
implanting ions to one end and the other end of the polycrystal silicon layer by an ion implantation technique, respectively;
performing rapid thermal anneal activation to the one end and the other end of the polycrystal silicon layer with the ion implanted; and
removing the remaining photoresist layer.

10. The method for manufacturing the lower temperature polycrystal silicon thin film transistor according to claim 8, wherein the step of forming one end of the exposed polycrystal silicon layer as the source electrode contact layer, and forming the other end of the polycrystal silicon layer as the drain electrode contact layer comprising;
implanting ions to one end and the other end of the polycrystal silicon layer by an ion implantation technique_{;} respectively;
performing rapid thermal anneal activation to the one end and the other end of the polycrystal silicon layer with the ion implanted; and
removing the remaining photoresist layer.

11. The method for manufacturing the lower temperature polycrystal silicon thin film transistor according to claim 5, wherein the etching stop layer is formed of silicon oxide and/or silicon nitride.

12. The method for manufacturing the lower temperature polycrystal silicon thin film transistor according to claim 9, wherein the implanting ions by the ion implantation technique is boron ions.

13. The method for manufacturing the lower temperature polycrystal silicon thin film transistor according to claim 10, wherein the implanting ions by the ion implantation technique is boron ions.
